(19) United States
(12) Patent Application Publication
(10) Pub. No.: US 2005/0134344 A1
(43) Pub. Date: Jun. 23, 2005

(54) Fast start-up circuit for a prescaler device

(75) Inventor: Yoonhyuk Ro, Melbourne, FL (US)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: Globespan Virata, Inc.

(21) Appl. No.: 10/740,895

(22) Filed: Dec. 22, 2003

(51) Int. Cl. H03K 3/02

(52) U.S. Cl. 327/198

(57) ABSTRACT

A method and system of the present inventions provide a fast start-up circuit for a prescaler device. A start-up circuit for reducing delay at a transition from a reset mode to a normal operation mode of a prescaler may include an input for receiving an input voltage; a first switch for biasing the input voltage at a source voltage during a reset mode; a second switch for generating an output voltage at ground during the reset mode; and an output for transmitting the output voltage to a counter; wherein the first switch and the second switch are disabled at a start of the normal operation mode and the input voltage is pulled down from the source voltage to less than approximately ½ of the source voltage during the transition so that the output makes a substantially full swing at a first pulse.

### FIELD OF THE INVENTION

The present invention relates generally to a fast start-up circuit, more particularly, to a fast start-up circuit for a prescaler device for reducing delay at a transition from a reset mode to a normal operation mode.

### BACKGROUND OF THE INVENTION

Prescaler devices may be used in various high speed applications including transceivers and other similar structures. In general, a prescaler may scale an input signal into a desired output signal. Further, a prescaler may divide an input signal into a plurality of desired output signals. Prescaler devices may also include a counter with a division ratio that may be switched from one value to another by a control signal.

A conventional self-biased prescaler output inverter generally misses several output pulses at a transition from a reset mode to a normal operation mode because the prescaler is AC coupled to an input signal through a capacitor with a large RC time constant. Since an output of self biased inverter does not swing rail to rail, some pulses are lost at the transition. Therefore, additional time is needed to reach a normal operating condition due to the large RC time constant.

Thus, the output voltage of the self biased inverter within a conventional prescaler does not swing rail to rail at the beginning of the transition and needs a couple of pulses to start full swing. As a result, a program counter receiving the output of the prescaler as input will likely miss a couple of pulse counts at the transition point, resulting in various inefficiencies. For example, this false delay is a problem for digital tuning applications because the prescaler is frequently reset for digital tuning.

Therefore, there is a need in the art of prescaler systems for a more efficient method and system for reducing delay at a transition from a reset mode to a normal operation mode.

### SUMMARY OF THE INVENTION

Aspects of the present inventions overcome the problems noted above, and realize additional advantages. A method and system of the present inventions.

In accordance with an exemplary embodiment, a start-up circuit for reducing delay at a transition from a reset mode to a normal operation mode of a prescaler comprises an input for receiving an input voltage; a first switch for biasing the input voltage at a source voltage during a reset mode; a second switch for generating an output voltage at ground during the reset mode; and an output for transmitting the output voltage to a counter; wherein the first switch and the second switch are disabled at a start of the normal operation mode and the input voltage is pulled down from the source voltage to less than approximately ½ of the source voltage during the transition so that the output makes a substantially full swing at a first pulse.

In accordance with other aspects of this exemplary embodiment, the first switch comprises a PFET circuit; the second switch comprises a NFET circuit; the first switch biases the input voltage at 3/4 of the source voltage during the reset mode; the first switch biases the input voltage between a range of approximately ½ of the source voltage to the source voltage during the reset mode; the first switch and the second switch are controlled by an inverter structure comprising a third switch and a fourth switch; the third switch comprises a PFET circuit and the fourth switch comprises a NFET circuit; a reset signal controls an input of the second switch and a complementary signal controls an input of the first switch; the input comprises an input to a self-based inverter; and the output makes a substantially full swing from ground at a first pulse.

In accordance with another exemplary embodiment, a method for implementing a start-up circuit for reducing delay at a transition from a reset mode to a normal operation mode of a prescaler comprises the steps of receiving an input voltage; biasing the input voltage at a source voltage by a first switch during a reset mode; generating an output voltage at ground by a second switch during the reset mode; and transmitting the output voltage to a counter; wherein the first switch and the second switch are disabled at a start of the normal operation mode and the input voltage is pulled down from the source voltage to less than approximately 1/2 of the source voltage during the transition so that the output makes a substantially full swing at a first pulse.

The accompanying drawings, which are incorporated in and constitute a part of this specification, illustrate various embodiments of the inventions and, together with the description, serve to explain the principles of the inventions.

### BRIEF DESCRIPTION OF THE DRAWINGS

The present inventions can be understood more completely by reading the following Detailed Description of the Invention, in conjunction with the accompanying drawings, in which:

FIG. 1 is a diagram illustrating a prescaler with a fast start-up circuit according to an embodiment of the present invention.

FIG. 2 is a diagram illustrating a detailed view of a fast start-up circuit according to an embodiment of the present invention.

FIG. 3 is a diagram illustrating performance of a conventional prescaler.

FIG. 4 is a diagram illustrating performance of a prescaler with a fast start-up circuit according to an embodiment of the present invention.

FIG. 5 is an illustration of a transceiver device that may encompass the inventive prescaler of an embodiment of the present invention.

### DETAILED DESCRIPTION OF THE INVENTION

The following description is intended to convey a thorough understanding of the inventions by providing a number of specific embodiments and details involving prescaler applications. It is understood, however, that the inventions are not limited to these specific embodiments and details, which are exemplary only. It is further understood that one possessing ordinary skill in the art, in light of known systems and methods, would appreciate the use of the inventions for their intended purposes and benefits in any number of alternative embodiments, depending upon specific design and other needs.

An embodiment of the present inventions is directed to a fast start-up circuit that provides that an inverter of a prescaler output generates correct pulses without missing any pulses at the transition from a Reset mode to a normal operation mode by biasing the input-side of the inverter and the output-side of the inverter at high and low during the Reset mode, respectively.

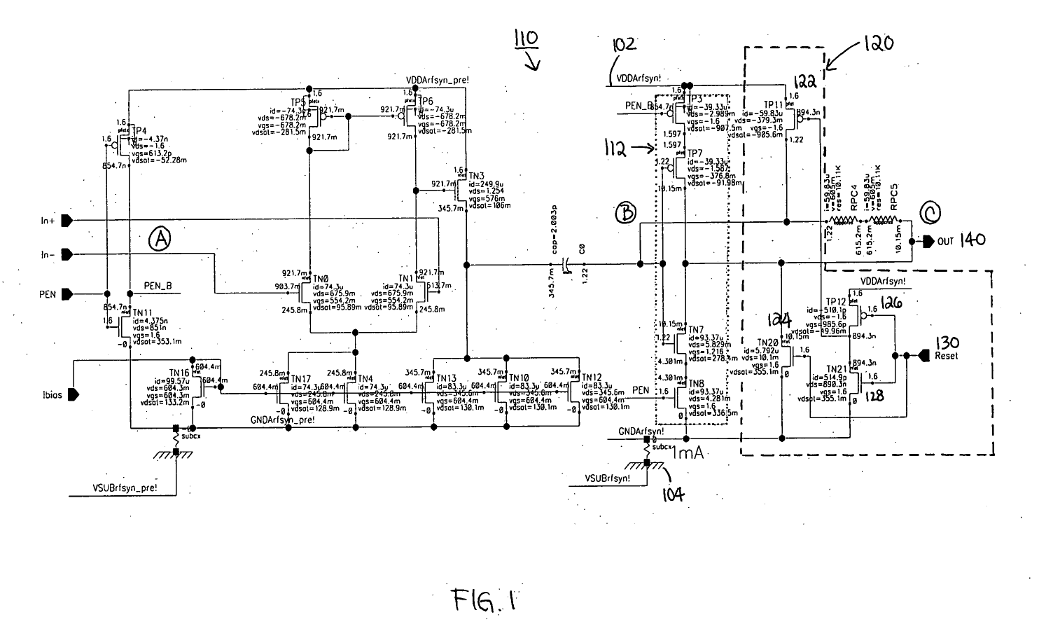

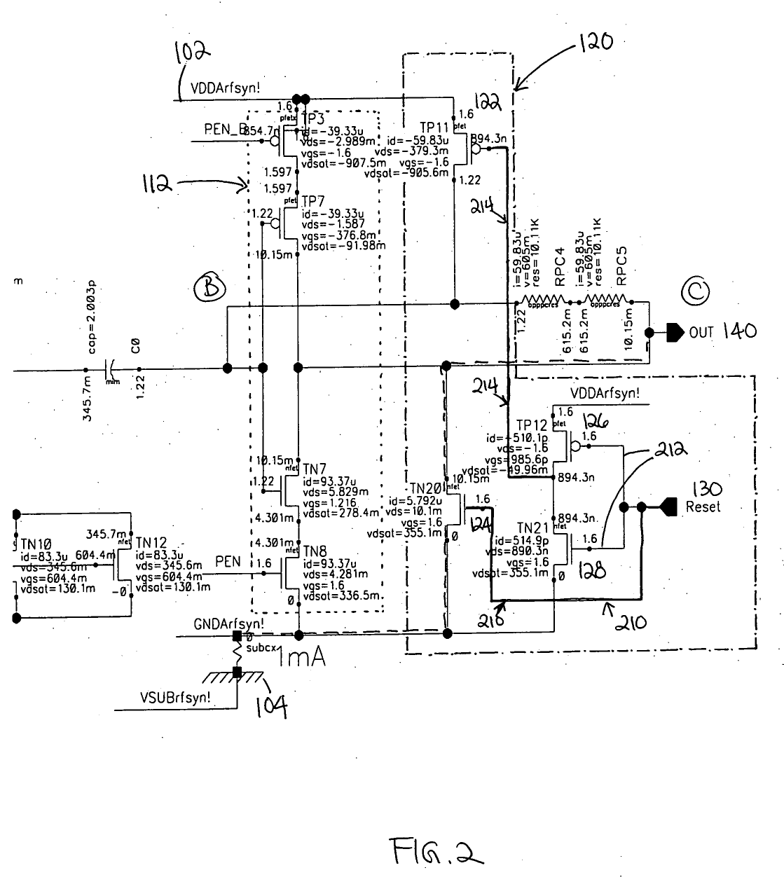

FIG. 1 is a diagram illustrating a prescaler with a fast start-up circuit according to an embodiment of the present invention. In this exemplary embodiment, prescaler 110 comprises a fast start-up circuit 120 in accordance with an embodiment of the present invention. An input to a self-biased inverter 112 is shown at node B and an output is shown at node C, or 140. The fast start-up circuit 120 may include a combination of switches and other circuitry. In this exemplary embodiment, prescaler 120 may include a first switch 122 and a second switch 124. The first switch 122 may represent a PFET component and the second switch 124 may represent a NFET component. Other components may be implemented as well. The first switch 122 takes an input voltage at node B and biases the input voltage at a source voltage VDD 102 or at least a fraction of VDD. The second switch 124 pulls down an output voltage to ground 104 for generating an output at ground at node C or 140. The values displayed in FIGS. 1 and 2 are one exemplary embodiment of the present invention.

First switch 122 and second switch 124 may be controlled by a controller. In this example, the controller may include a third switch 126 and fourth switch 128. Other circuitry and components may be implemented.

FIG. 2 is a diagram illustrating a detailed view of a fast start-up circuit according to an embodiment of the present invention. As shown in FIG. 2, the controller may be controlled by a Reset signal generated at 130. In this example, controller may include third switch 126 and fourth switch 128. Third switch 126 may include a PFET component and fourth switch 128 may include a NFET component. Other components may be implemented. A Reset signal may be received by second switch 124, as shown by 210. A Reset signal may be received by third switch 126 and fourth switch 128 via 212. An output signal generated by third switch 126 and fourth switch 128 may be received by first switch 122, as shown by 214. In this illustration, the output signal of third switch 126 and fourth switch 128 may be identified as a complementary signal, Reset_Bar signal. Thus, the Reset signal is received at second switch 124 and the complementary signal Reset_Bar is received at first switch 122.

At a reset mode, first switch 122 biases an input voltage at node B to VDD or a fraction of VDD (e.g., ¾ VDD, etc.). Also during the reset mode, an output voltage at node C is pulled to ground 104 by second switch 124. In addition, Reset signal and Reset_Bar signal may be VDD and ground during the reset mode, respectively.

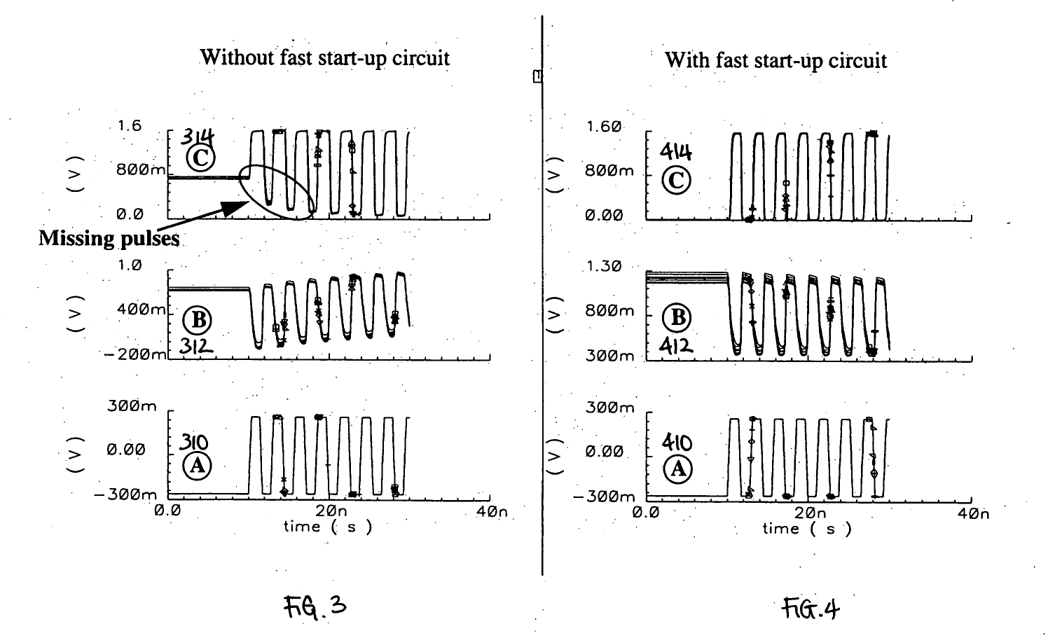

FIG. 3 is a diagram illustrating performance of a conventional prescaler. Chart 310 illustrates the voltage at node A. Chart 312 illustrates the voltage at node B, more specifically, an input voltage of self-biased inverter 112. As shown, normal operation condition is reached gradually. Chart 314 illustrates the voltage at an output 140, node C, without the fast start-up circuit 120 of an embodiment of the present invention. As illustrated, several pulses are missing which will lead to errors in accounting for clocks at a counter, coupled to output 140.

Flip-flop outputs are connected to the In + and In− (A of FIG. 1) of the output stage of the prescaler and they are 0 and 1 at In + and In−, respectively, during the reset mode. They start to swing at the transition of reset mode to normal operation mode (310 of FIG. 3). However, the input voltage (312 of FIG. 3) of the self biased inverter should reach the normal operation condition slowly. Therefore, the output voltage (314 of FIG. 3) of the self biased inverter does not swing rail to rail at the beginning of the transition and needs a couple of pulses to start full swing. As a result, a device, such as a program counter, which receives the output of the prescaler as input may miss a couple of pulse counts at the transition point.

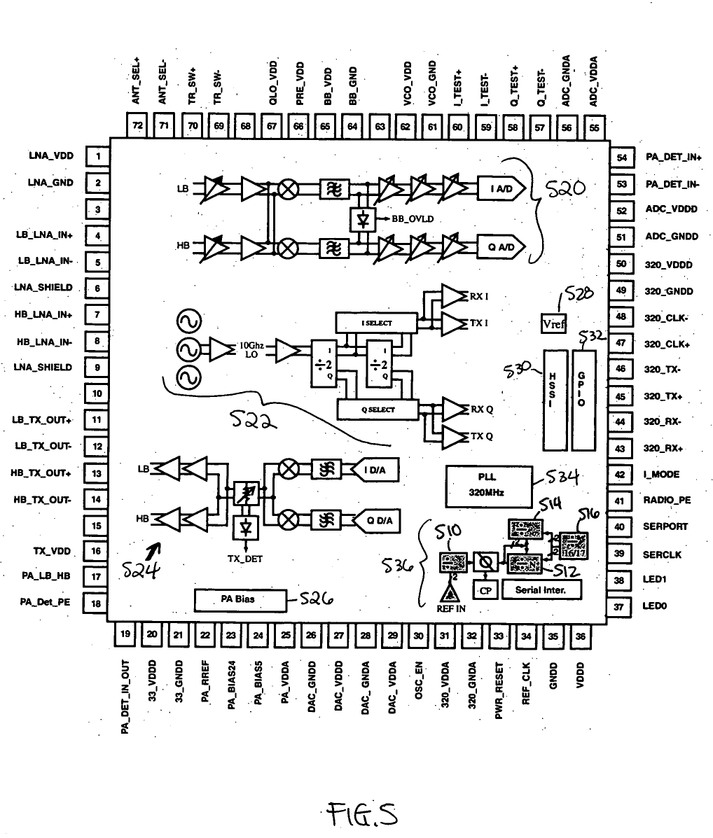

FIG. 4 is a diagram illustrating performance of a prescaler with a fast start-up circuit according to an embodiment of the present inventions. Chart 410 illustrates the voltage at node A. Chart 412 illustrates the voltage at node B, more specifically, input voltage of self-biased inverter 112. As shown, the input voltage is pulled up high by first switch 122. Chart 414 illustrates the voltage at an output 140, node C, with the fast start-up circuit 120 of an embodiment of the present invention. As illustrated, the voltage makes a full swing from the first pulse from ground.

Two switches (PFET 122 and NFET 124) may be controlled by Reset_bar and Reset signals. The PFET 122 will make the input voltage of the self biased inverter at ¾ of VDD (or other fraction of VDD) and NFET 124 will make the output voltage of the self biased inverter at GND during the reset mode. The input node B of the self biased inverter will be pulled down hard from VDD to GND when normal operation starts. As a result, the output voltage 414 of the self biased inverter makes a full swing from the first pulse when normal operation starts. Therefore, a device, such as a program counter will receiver correct pulses from the output stage of the prescaler.

The fast start-up circuit of an embodiment of the present inventions provides that the prescaler generates an output pulse correctly without a delay at a transition from Reset mode to normal operation mode. Therefore, a program counter (or other device), which uses output pulses of the prescaler as input signals, may start counting without a false delay.

In accordance with various embodiments of the present invention, the inventive features associated with the prescaler as discussed above may be incorporated in various devices and systems. According to one exemplary embodiment, the prescaler with the fast start-up circuit may be incorporated in a transceiver device. FIG. 5 is an illustration of a transceiver device that may encompass the inventive prescaler of an embodiment of the present invention. More specifically, the prescaler with the fast start-up circuit of an embodiment of the present invention may be incorporated in the prescaler as shown by 516, with Reference Counter 510 and Program Counters 512 and 514.

The transceiver of FIG. 5 may include Receiver 520, Quadrature Local Oscillator (QLO) 522, Transmitter 524, Power Amplifier (PA) Bias 526, Reference Voltage Generator 528, High Speed Serial Interface (HSSI) 530, General Purpose Input Output (GPIO) 532, Phase Lock Loop (PLL) 534 and Synthesizer 536.

The transceiver of FIG. 5 includes an entire Radio Frequency (RF)/analog Zero Intermediate Frequency (ZIF) frontend, entire Analog Front End (AFE) (including Analog to Digital (A/Ds) and Digital to Analog (D/As) converters) section, and 100K+ gates of baseband digital circuitry. The RF/analog features may include up-integration applications; support of 802.11b, 11g and 11a standards as well as half channel operation; integration of ZIF transceiver, AFE (converters), 320 MHz high speed serial interface Joint Electron Device Engineering Council (JEDEC) JC-61 compatible, and digital baseband circuitry on one Integrated Circuit (IC); 1.62-1.98 V supplies; overcomes inherently lower transconductance, higher offset voltages, and large flicker noise associated with CMOS technology; integrated synthesizer including a 3 core selectable 9-12 GHz Voltage Controlled Oscillator (VCO) and programmable loop filters; automatic digital/analog VCO tuning algorithm with real time digital control feedback and overwrite features; programmable 8/9 and 16/17 prescaler; two fractional N synthesizer designs with internal sigma delta modulators and programmability options as well as integer design; improved charge pump design to minimize mismatches critical to Fractional N performance; precision quadrature Local Oscillator (LO) generation circuitry designed to work across >4 GHz frequency range with many programmable tuning and optimization options; built-in frequency tracking option; LO mixer driver circuitry features programmable tuning and new CMOS level drive capability; 60 db digitally controlled Transmit (Tx) gain and 1 db resolution; Tx power inherently reduced as Tx gain is lowered to save power; Tx programmable tuning supports 2.4-2.5 GHz and 4.9-6 GHz operation; integrated Tx power combiner; fully integrated Tx 3^{rd} order Chebyshev filter with programmable half channel option; use of integrated transformers and dual inductors; Rx circuitry features almost 50% lower operating currents from previous ZIF designs; Rx RF circuitry supports 2.4-2.5 GHz and 4.9-6 GHz operation; Rx Mixer PMOS core optimized for low flicker noise performance and current amplifier interface circuitry to the Rx Low Pass Filter (LPF); automatic Rx/Tx filter calibration circuitry to tune out RC time constant variations; fully integrated Rx 6^{th} order Butterworth filter with programmable half channel option; fully differential common mode feedback amplifier with high bandwidth utilized in Rx LPF and Rx Automatic Gain Control (AGC) circuitry; +/−1 db accurate Rx detected with integrated filter; fully integrated Rx offset and AGC interfaces; built-in test multiplexing capability to allow visibility throughout transceiver circuitry; reuse of converters on Rx and Tx required solving interface issues; full suite of test modes to add in exercising all circuitry and providing diagnostic capability including across AFE, JC-61 and digital sections; and at least 250 programmable bits used for operation modes and flexibility to limit options and rework and electrically readable metal options.

While the foregoing description includes many details and specificities, it is to be understood that these have been included for purposes of explanation only, and are not to be interpreted as limitations of the present inventions. Many modifications to the embodiments described above can be made without departing from the spirit and scope of the inventions.

The present inventions are not to be limited in scope by the specific embodiments described herein. Indeed, various modifications of the present inventions, in addition to those described herein, will be apparent to those of ordinary skill in the art from the foregoing description and accompanying drawings. Thus, such modifications are intended to fall within the scope of the following appended claims. Further, although the present inventions have been described herein in the context of a particular implementation in a particular environment for a particular purpose, those of ordinary skill in the art will recognize that its usefulness is not limited thereto and that the present inventions can be beneficially implemented in any number of environments for any number of purposes. Accordingly, the claims set forth below should be construed in view of the full breath and spirit of the present inventions as disclosed herein.

1. A start-up circuit for reducing delay at a transition from a reset mode to a normal operation mode of a prescaler, the start-up circuit comprising:
an input for receiving an input voltage;
a first switch for biasing the input voltage at a source voltage during a reset mode;
a second switch for generating an output voltage at ground during the reset mode; and
an output for transmitting the output voltage to a counter;
wherein the first switch and the second switch are disabled at a start of the normal operation mode and the input voltage is pulled down from the source voltage to less than approximately ½ of the source voltage during the transition so that the output makes a substantially full swing at a first pulse.

2. The circuit of claim 1, wherein the first switch comprises a PFET circuit.

3. The circuit of claim 1, wherein the second switch comprises a NFET circuit.

4. The circuit of claim 1, wherein the first switch biases the input voltage at 3/4 of the source voltage during the reset mode.

5. The circuit of claim 1, wherein the first switch biases the input voltage between a range of approximately ½ of the source voltage to the source voltage during the reset mode.

6. The circuit of claim 1, wherein the first switch and the second switch are controlled by an inverter structure comprising a third switch and a fourth switch.

7. The circuit of claim 6, wherein the third switch comprises a PFET circuit and the fourth switch comprises a NFET circuit.

8. The circuit of claim 7, wherein a reset signal controls an input of the second switch and a complementary signal controls an input of the first switch.

9. The circuit of claim 1, wherein the input comprises an input to a self-based inverter.

10. The circuit of claim 9, wherein the output makes a substantially full swing from ground at a first pulse.

11. A method for implementing a start-up circuit for reducing delay at a transition from a reset mode to a normal operation mode of a prescaler, the method comprising the steps of:
receiving an input voltage;
biasing the input voltage at a source voltage by a first switch during a reset mode;
generating an output voltage at ground by a second switch during the reset mode; and
transmitting the output voltage to a counter;
wherein the first switch and the second switch are disabled at a start of the normal operation mode and the input voltage is pulled down from the source voltage to less than approximately 1/2 of the source voltage during the transition so that the output makes a substantially full swing at a first pulse.

12. The method of claim 11, wherein the first switch comprises a PFET circuit.

13. The method of claim 11, wherein the second switch comprises a NFET circuit.

14. The method of claim 11, wherein the first switch biases the input voltage at 3/4 of the source voltage during the reset mode.

15. The method of claim 11, wherein the first switch biases the input voltage between a range of approximately ½ of the source voltage to the source voltage during the reset mode.

16. The method of claim 11, wherein the first switch and the second switch are controlled by an inverter structure comprising a third switch and a fourth switch.

17. The method of claim 16, wherein the third switch comprises a PFET circuit and the fourth switch comprises a NFET circuit.

18. The method of claim 17, wherein a reset signal controls an input of the second switch and a complementary signal controls an input of the first switch.

19. The method of claim 11, wherein the input comprises an input to a self-based inverter.

20. The method of claim 19, wherein the output makes a substantially full swing from ground at a first pulse.

21. At least one signal embodied in at least one carrier wave for transmitting a computer program of instructions configured to be readable by at least one processor for instructing the at least one processor to execute a computer process for reducing delay at a transition from a reset mode to a normal operation mode of a prescaler by performing the steps of:
receiving an input voltage;
biasing the input voltage at a source voltage by a first switch during a reset mode;
generating an output voltage at ground by a second switch during the reset mode; and
transmitting the output voltage to a counter;
wherein the first switch and the second switch are disabled at a start of the normal operation mode and the input voltage is pulled down from the source voltage to less than approximately 1/2 of the source voltage during the transition so that the output makes a substantially full swing at a first pulse.
